(19) United States
(12) Patent Application Publication
(10) Pub. No.: US 2008/0166864 A1
(43) Pub. Date: Jul. 10, 2008

(54) METHOD FOR FORMING TRENCH GATE AND METHOD FOR MANUFACTURING SEMICONDUCTOR DEVICE

(75) Inventor: Hiromitsu OSHIMA, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 11/969,506

(22) Filed: Jan. 4, 2008

(30) Foreign Application Priority Data
Jan. 9, 2007 (JP) 2007-001199

(51) Int. Cl. H01L 21/283

(52) U.S. Cl. 438/589; 257/E21.158

(57) ABSTRACT

A method for forming trench gates is provided with a step of forming gate trenches on a semiconductor substrate, and a step of forming an element isolation region on the semiconductor substrate on which the gate trenches are formed. A step of channel doping within the gate trenches is performed before the element isolation region is formed and after the gate trenches are formed. The method for forming the trench gate is further provided with a step of forming a gate oxide film on the inner wall of the gate trenches, and a step of embedding a gate electrode material within the gate trenches.

### TECHNICAL FIELD

The present invention relates to a method for forming trench gates in a transistor having trench gate structure. Further, the present invention relates to a method for manufacturing a semiconductor device having a trench gate type transistor.

### BACKGROUND OF THE INVENTION

The recent miniaturization of DRAM (Dynamic Random Access Memory) cells has been accompanied by the necessity of shortening the gate length of cell transistors. However, when the gate length becomes shorter, the short-channel effect of the transistor becomes significant, and a threshold voltage of the transistor decreases by increased sub-threshold current. When an impurity concentration of a silicon substrate is increased in order to suppress the decrease of the threshold voltage, a junction leakage increases, and deterioration of the refresh characteristics in the DRAM becomes a severe drawback.

A so-called trench-gate-type transistor (also referred to as a recess channel transistor) in which a gate electrode is embedded in a trench formed on a silicon substrate has been emphasized as a means of overcoming these drawbacks (see Japanese Laid-open Patent Application No. 2006-135117). According to this transistor, an effective channel length (a gate length) can be physically and sufficiently secured, and a fine DRAM having a process rule of 90 nm or less can be achieved.

FIGS. 11A, 11B, 11C and FIGS. 12A, 12B, 12C are explanatory diagrams of a conventional method for forming trench gates. FIG. 11A shows a plane layout of trench gates, FIG. 11B is a cross-sectional view of the trench gate along a X-X line in FIG. 11A, and FIG. 11C is a cross-sectional view of the trench gate along a Y-Y line in FIG. 11A. FIG. 12A shows a plane layout of trench gates, FIG. 12B is a cross-sectional view of the trench gate along a X-X line in FIG. 12A, and FIG. 12C is a cross-sectional view of the trench gate along a Y-Y line in FIG. 12A.

As shown in FIGS. 11A, 11B, and 11C, in the conventional method for forming trench gates, active regions 41 are first formed on a silicon substrate 40. The active regions 41 are island-shaped regions isolated from each other by an element isolation region 42, and are usually formed by the STI (Shallow Trench Isolation) method. Specifically, an element isolation trench is first formed on the silicon substrate 40, and then a silicon oxide film (a field oxide film) is deposited on this element isolation trench by CVD (Chemical Vapor Deposition). Thereafter, an unnecessary field oxide film on the silicon substrate 40 is removed by the CMP (Chemical Mechanical Polishing), and the field oxide film is left on only the inside of the element isolation trench, thereby forming an element isolation region (an STI region) 42 and the active regions 41.

Next, as shown in FIGS. 12A, 12B, and 12C, linear trenches (gate trenches) 43 crossing the active regions 41 are formed. Each gate trench 43 is formed by photolithography and dry etching, using a silicon nitride film as a hardmask. Each gate trench 43 is simultaneously formed on the element isolation region 42 and on the active regions 41. Thereafter, a gate oxide film is formed on an inner wall of the gate trench 43. Further, a gate electrode material such as a polysilicon film and tungsten is embedded into the gate trench, thereby completing the trench gate.

In the formation of the trench gate, a width and a depth of the gate trench 43 within the active region 41 are preferably constant, and a silicon substrate material within the gate trench 43 is preferably securely removed. When the silicon substrate material remains in the trench 43, the securing of the channel length becomes uncertain, and that adversely affects the characteristic of the cell transistor.

However, according to the conventional method described above, as shown in FIGS. 13A and 13B, at the time of forming the gate trench 43, a protruded part 42x of the element isolation region 42 serves as a mask when etching the gate trench 43. Therefore, an ideal trench shape as shown in FIG. 12C cannot be obtained, and the silicon substrate material remains at a part 42y which is in contact with the side surface of the element isolation region 42. In other words, the protruded part 42x of the element isolation region becomes the cause of generating many flashes of the silicon substrate material.

The flashes can be reduced by increasing the amount of etching to form the trench. By increasing the etching amount, the protruded part 42x of the element isolation region 42 can be removed. By decreasing the protruded amount of the element isolation region 42, the occurrence of flashes can be suppressed. However, when the etching amount is increased to remove the protruded part 42x, a trench shape having a proper width as shown in FIG. 12B cannot be obtained in the element isolation region 42, and a width W₀ of the gate trench 43 on the element isolation region 42 becomes too large, as shown in FIG. 14A. When the width W₀ is too large, the etching amount of the gate electrode material on the element isolation region 42 becomes insufficient at the formation of the gate electrodes, and gate electrodes 44b on the element isolation region 42 form a skirt shape, as shown in FIG. 14B. This becomes a cause of generating a short-circuiting between the cell contact and the gate electrodes.

### SUMMARY OF THE INVENTION

It is therefore an object of the present invention to provide a method for forming trench gates having a satisfactory characteristic, without generating a problem of a short-circuiting of a cell contact and without leaving flashes of a silicon substrate material within a gate trench.

Another object of the present invention is to provide a method for manufacturing a semiconductor device including trench gate type transistor having a satisfactory characteristic, without having a short-circuiting of a cell contact and without leaving flashes of a silicon substrate material within a gate trench.

The above and other object of the present invention can be accomplished by a method for forming trench gates comprising the steps of forming gate trenches on a semiconductor substrate, and forming an element isolation region on the semiconductor substrate on which the gate trenches are formed. According to the present invention, occurrence of flashes of the silicon substrate material can be prevented, and a gate trench of an ideal shape can be formed.

In a preferred aspect of the present invention, the method for forming trench gates further comprises a step of channel doping within the gate trenches before the element isolation region is formed after the gate trenches are formed. Accordingly, a channel region can be formed securely between a source and a drain region.

In a further preferred aspect of the present invention, the method for forming trench gates further comprises the steps of forming a gate oxide film on the inner wall of the gate trenches, and embedding a gate electrode material within the gate trenches. Accordingly, the trench gate can be securely formed.

In the present invention, the element isolation region is preferably formed by the STI method. According to the STI method, a boundary surface between the element isolation region and an active region can be made sharp, and the element isolation region can be narrowed. However, because a protruded part that becomes the cause of generating flashes of the silicon substrate material is present, a significant effect of the present invention can be obtained.

In a preferred aspect of the present invention, the step of forming the element isolation region includes the steps of forming an element isolation trench so as to form trenches that reflect the gate trenches on the bottom of the element isolation trench, embedding an element isolation film in the element isolation trench, and polishing the surface of the element isolation film.

The above and other object of the present invention can also be accomplished by a method for manufacturing a semiconductor device comprising the steps of forming gate trenches on a semiconductor substrate, channel doping within the gate trenches, forming an element isolation region on the semiconductor substrate on which the gate trenches are formed, forming a gate oxide film on the inner wall of the gate trenches, and embedding a gate electrode material within the gate trenches.

### BRIEF DESCRIPTION OF THE DRAWINGS

The above and other objects, features and advantages of this invention will become more apparent by reference to the following detailed description of the invention taken in conjunction with the accompanying drawings, wherein:

FIGS. 1A and 1B are schematic cross-sectional views showing a manufacturing process of a cell transistor of a DRAM according to one preferred embodiment of the present invention (specifically forming a silicon nitride film 12);

FIGS. 2A and 2B are schematic cross-sectional views showing a manufacturing process of the cell transistor of the DRAM according to one preferred embodiment of the present invention (specifically forming gate trenches 10a);

FIG. 3 is a plane layout of a silicon substrate 10 on which the gate trenches 10a are formed;

FIG. 4 is a schematic cross-sectional view taken along Y-Y line in FIG. 3;

FIGS. 5A and 5B are schematic cross-sectional views showing a manufacturing process of the cell transistor of the DRAM according to one preferred embodiment of the present invention (specifically channel doping);

FIGS. 6A, 6B and 6C are schematic cross-sectional views showing a manufacturing process of the cell transistor of the DRAM according to one preferred embodiment of the present invention (specifically forming a trench for STI);

FIGS. 7A and 7B are schematic cross-sectional views showing a manufacturing process of the cell transistor of the DRAM according to one preferred embodiment of the present invention (specifically forming STI);

FIG. 8 is a plane layout of the silicon substrate 10 on which the active regions 17 are formed;

FIGS. 9a, 9b and 9c are schematic cross-sectional views showing a manufacturing process of the cell transistor of the DRAM according to one preferred embodiment of the present invention (specifically forming gate electrodes);

FIG. 10 is a schematic cross-sectional view showing a manufacturing process of the cell transistor of the DRAM according to one preferred embodiment of the present invention (specifically showing a complete cell transistor);

FIGS. 11A, 11B, and 11C are explanatory diagrams of a conventional method for forming trench gates;

FIGS. 12A, 12B, and 12C are explanatory diagrams of a conventional method for forming trench gates;

FIGS. 13A and 13B are schematic cross-sectional views for explaining one problem of the conventional method for forming the trench gate; and

FIGS. 14A and 14B are schematic cross-sectional views for explaining another problem of the conventional method for forming the trench gate.

### DETAILED DESCRIPTION OF THE EMBODIMENTS

Preferred embodiments of the present invention will now be described in detail hereinafter with reference to the accompanying drawings.

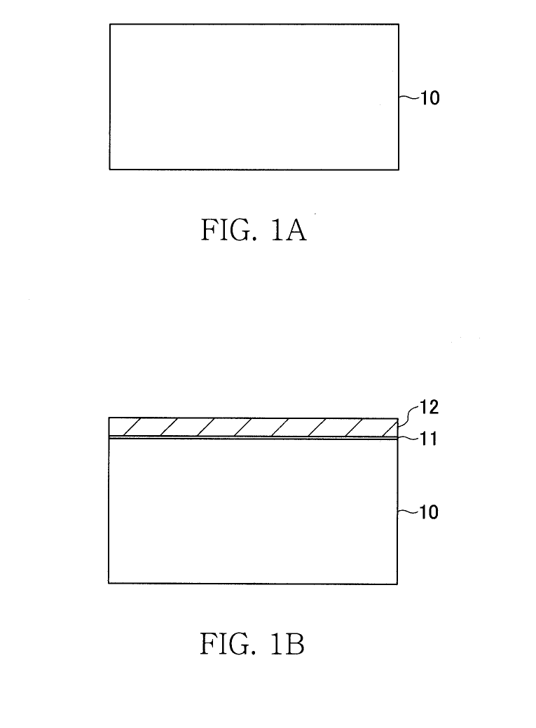

FIGS. 1A and 1B to FIG. 10 are schematic views of a manufacturing process of a cell transistor of a DRAM to which a method for forming trench gates according to an exemplary embodiment of the present invention is applied.

In the method for manufacturing a cell transistor according to the embodiment, a gate trench is first formed on a silicon substrate, as shown in FIGS. 1A and 1B to FIGS. 5A and 5B.

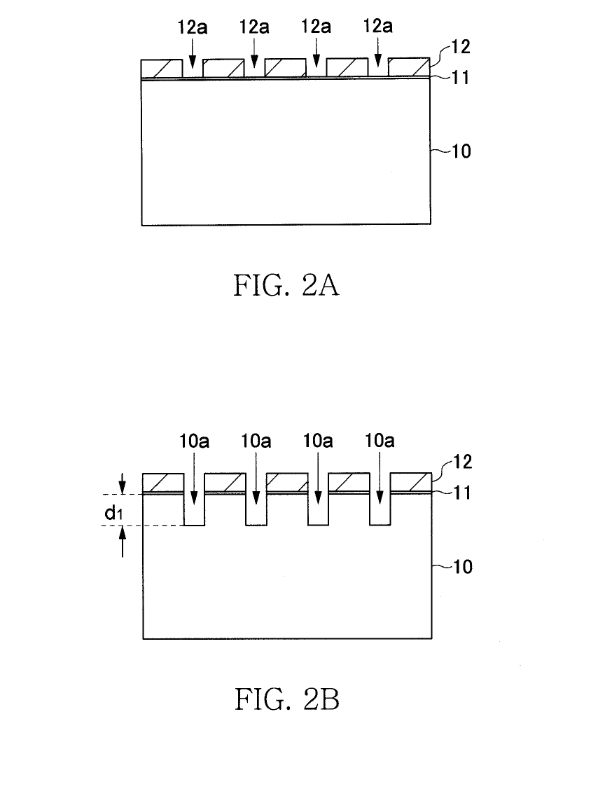

In the formation of the gate trench, a p-type silicon substrate 10 is first prepared (FIG. 1A), and a thin silicon-oxide film 11 is formed on this silicon substrate 10 by thermal oxidation. Further, a silicon nitride film 12 is formed by CVD (FIG. 1B). Next, the silicon nitride film 12 in the region which is to become the gate trench is removed by photolithography and dry etching, thereby forming opening patterns 12a (FIG. 2A). The silicon oxide film 11 and the silicon substrate 10 are dry etched, using the silicon nitride film 12 as a hardmask, thereby forming gate trenches 10a (FIG. 2B).

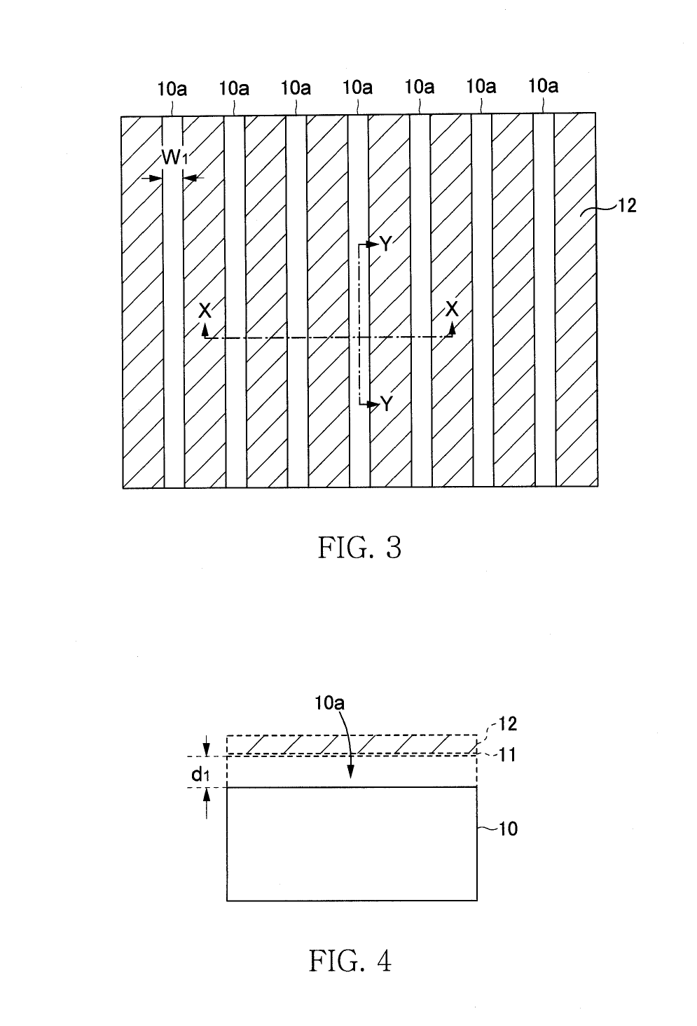

FIG. 3 shows a plane layout of the silicon substrate 10 on which the gate trenches 10a are formed, and a schematic cross-sectional view taken along X-X line in FIG. 3 corresponds to FIG. 2B. FIG. 4 is a schematic cross-sectional view along Y-Y line in FIG. 3. As shown in FIG. 3, many linear gate trenches 10a are aligned at a predetermined pitch on the silicon substrate 10. Although not particularly limited, each trench has a width W₁ of about 35 nm, and a depth d₁ of about 140 nm.

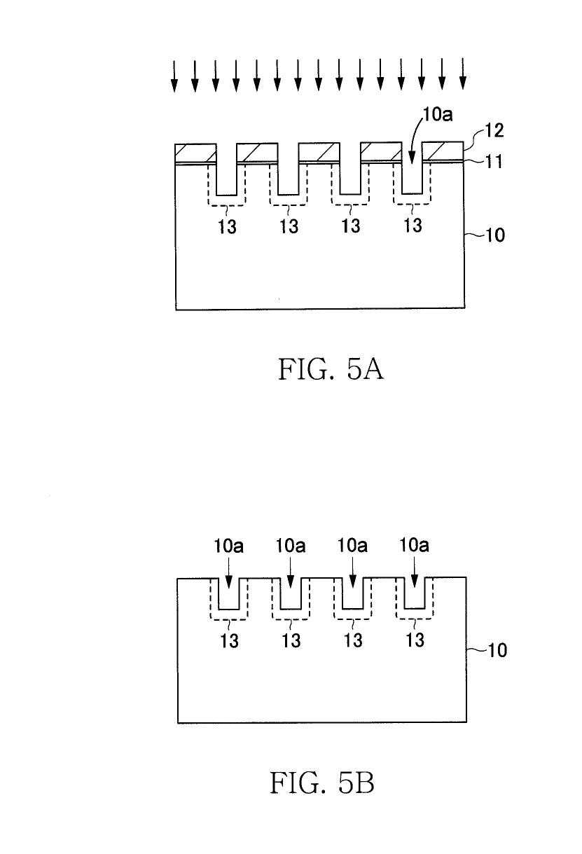

An impurity such as boron (B) is ion implanted, directly using the silicon nitride film 12 as a mask, thereby performing a channel doping into a channel region (FIG. 5A). As a result, channel regions 13 are formed. Thereafter, the silicon nitride film 12 and the silicon oxide film 11 are removed, thereby completing the channel-doped gate trenches 10a (FIG. 5B). These channels are called “recess channels”.

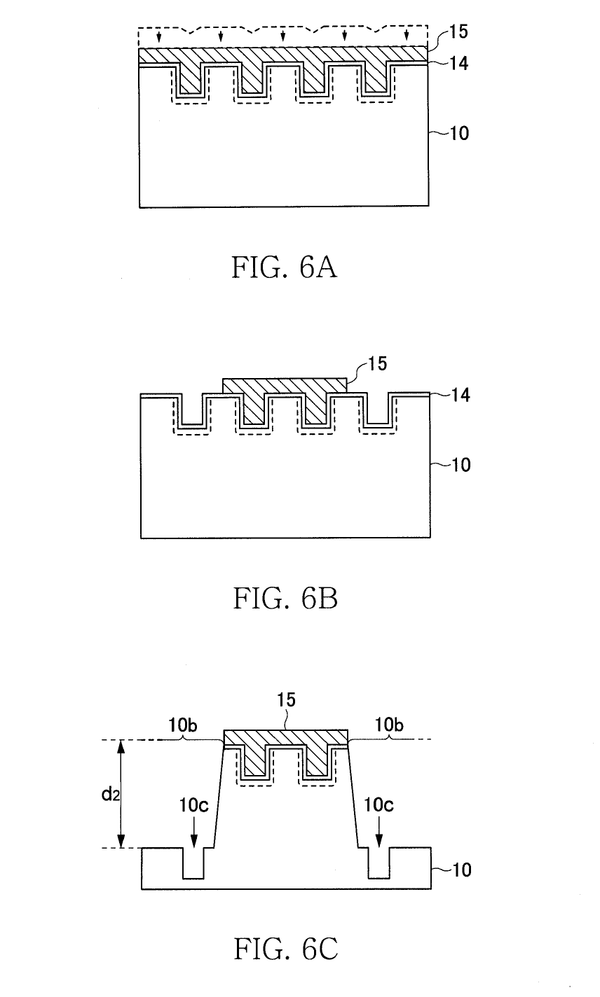

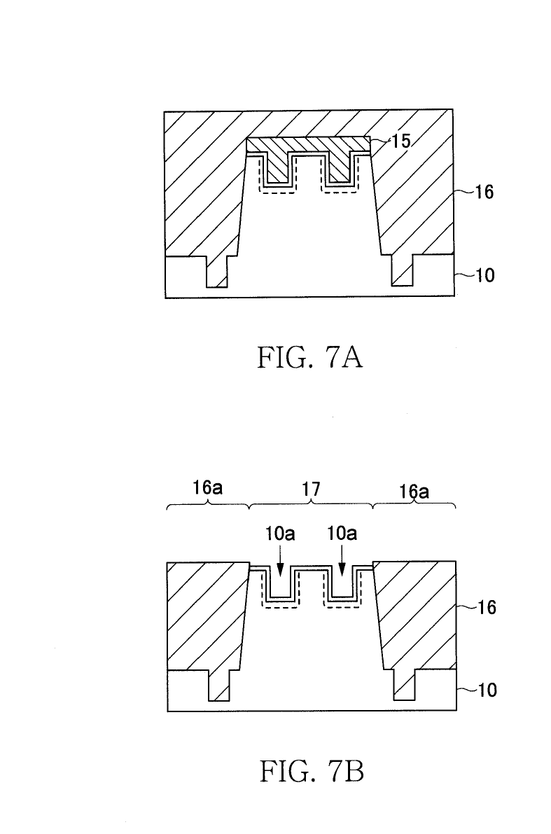

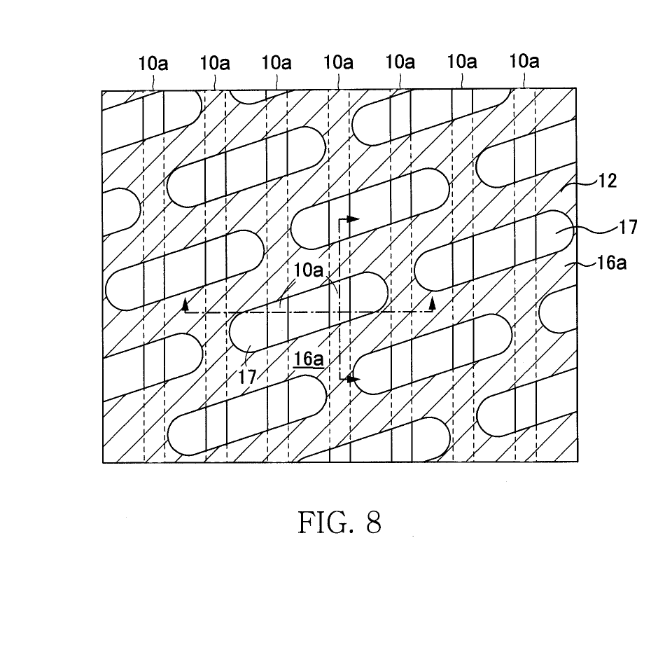

As shown in FIGS. 6A, 6B, 6C and FIGS. 7A and 7B, an element isolation region is formed by the STI method on the silicon substrate 10 on which the gate trenches 10a are already formed.

In the formation of the element isolation region, a thin silicon oxide film 14 is formed on the silicon substrate 10 by thermal oxidation, and a silicon nitride film 15 is formed on the silicon oxide film 14 by CVD (FIG. 6A). In this case, a thickness of the silicon nitride film 15 is preferably about 120 nm from the surface of the substrate. Thereafter, the surface of the silicon nitride film 15 is flattened by CMP.

The silicon nitride film 15 in the region other than that becoming the active region is removed by photolithography and dry etching (FIG. 6B). As a result, the surface of the silicon substrate 10 is covered with the silicon nitride film 15 by only the region which is to become the active region.

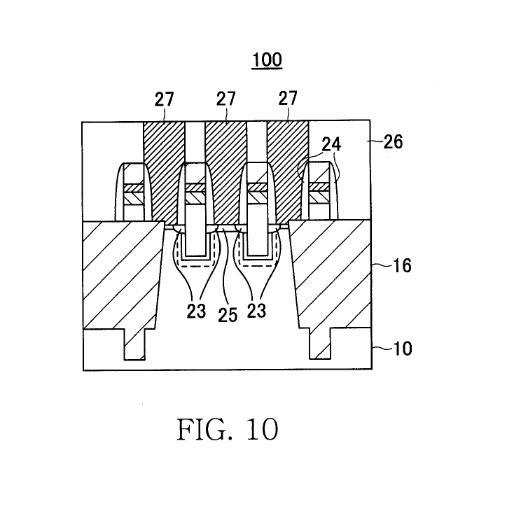

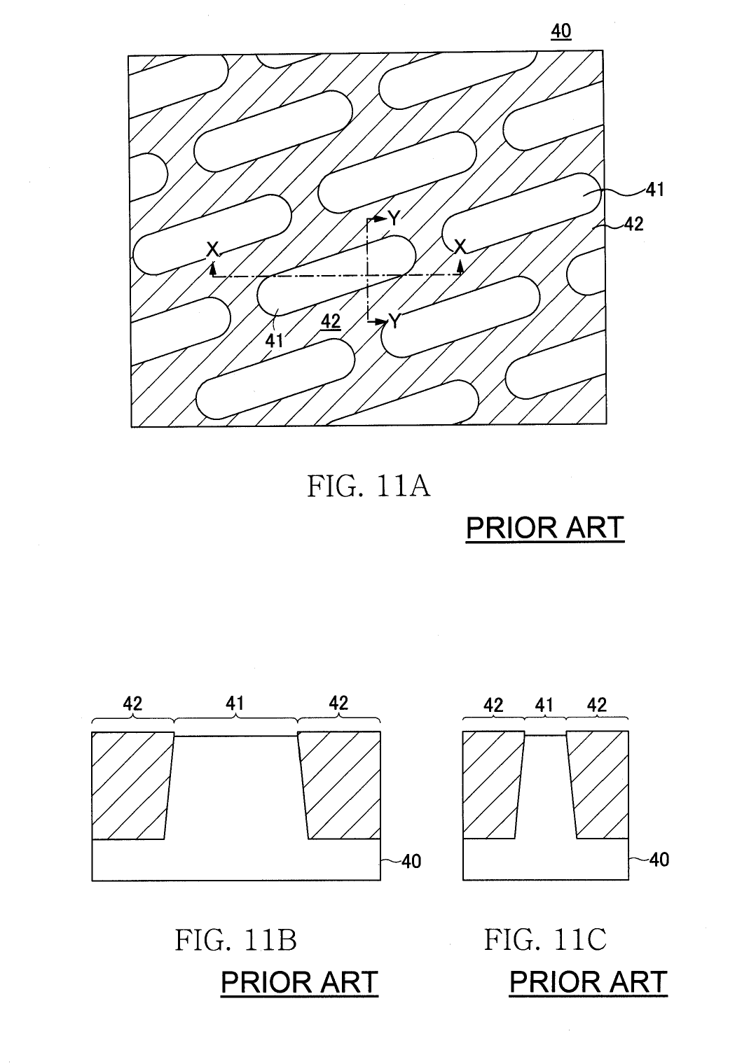

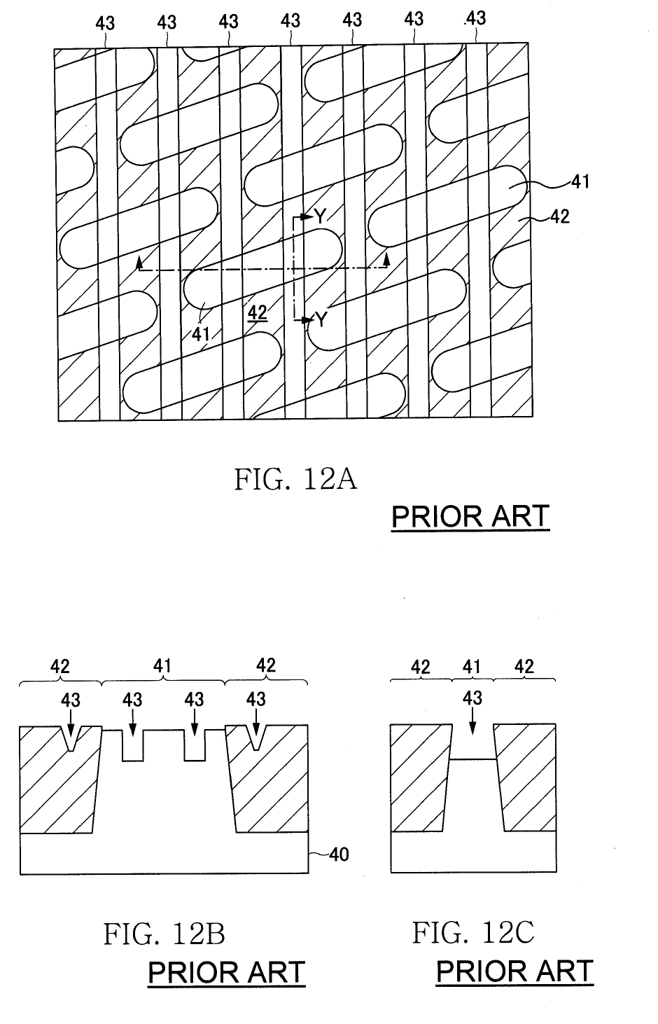

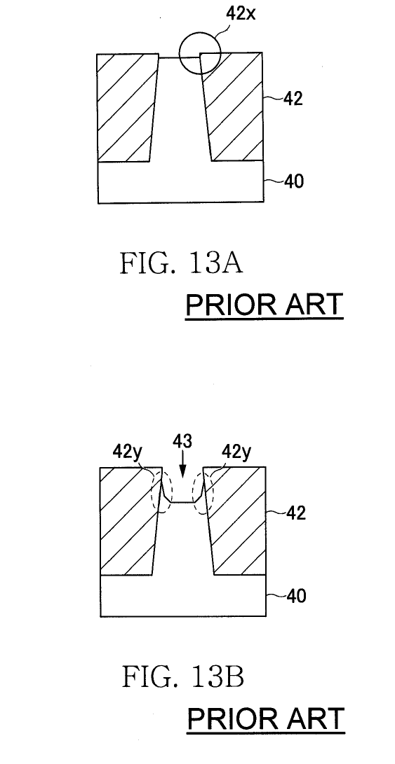

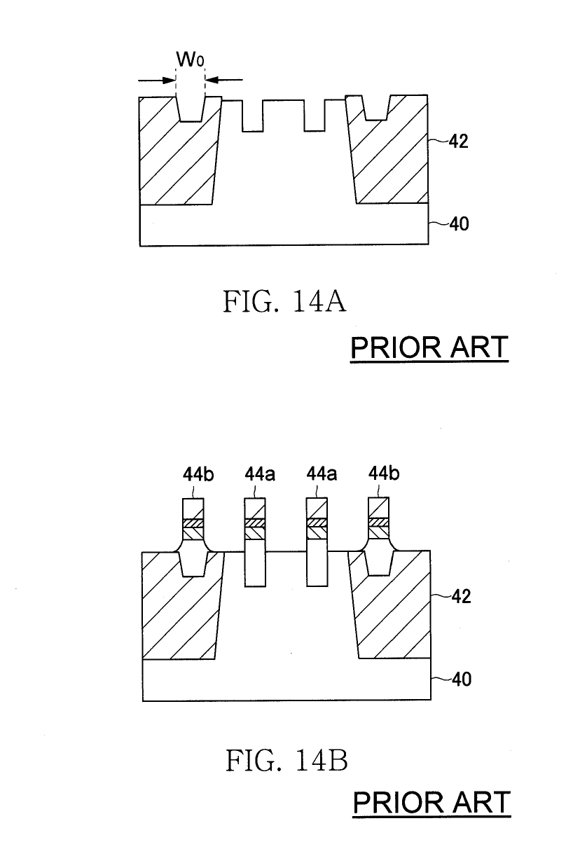

Next, the silicon oxide film 14 and the silicon substrate 10 are dry etched, using the silicon nitride film 15 as a hardmask, thereby forming element isolation trenches 10b (FIG. 10C). In this case, a trace (a recess) 10c of the gate trench 10a remains on the bottom of each element isolation trench 10b. However, this recess 10c does not affect the subsequent manufacturing process or the characteristic of the cell transistor. Although not particularly limited, a depth d₂ of the element isolation trench 10b is set about 200 to 350 nm.

Next, the silicon substrate 10 is thermally oxidized at about 1,000° C., thereby forming a thin silicon-oxide film (not shown) having a thickness of about 10 nm on an inner wall of the element isolation trench 10b. Thereafter, a silicon oxide film 16 having a thickness of about 450 to 500 nm is deposited by CVD (FIG. 7A). As a result, the silicon oxide film (element isolation film) is embedded in the element isolation trench 10b. Thereafter, the surface of the silicon oxide film 16 is polished until the silicon nitride film 15 is exposed by CMP. Then, the silicon nitride film 15 is removed by dry etching (FIG. 7B). Through the above process, an element isolation region 16a is formed, and plural active regions 17 mutually isolated by the element isolation region 16a are also formed.

FIG. 8 shows a plane layout of the silicon substrate on which the active regions 17 are formed.

As shown in FIG. 8, the active regions 17 are slender island-shaped regions mutually isolated by the element isolation region 16a. A longitudinal direction of each active region 17 forms a predetermined angle with a layout direction of the gate trenches 10a. Each active region 17 crosses two gate trenches 10a. Because the inside of the gate trench 10a passing the element isolation region 16a is embedded with the silicon oxide film (a field oxide film) 16, no gate trench 10a is present in the element isolation region 16a. As a result, the surface of the element isolation region 16a becomes flat.

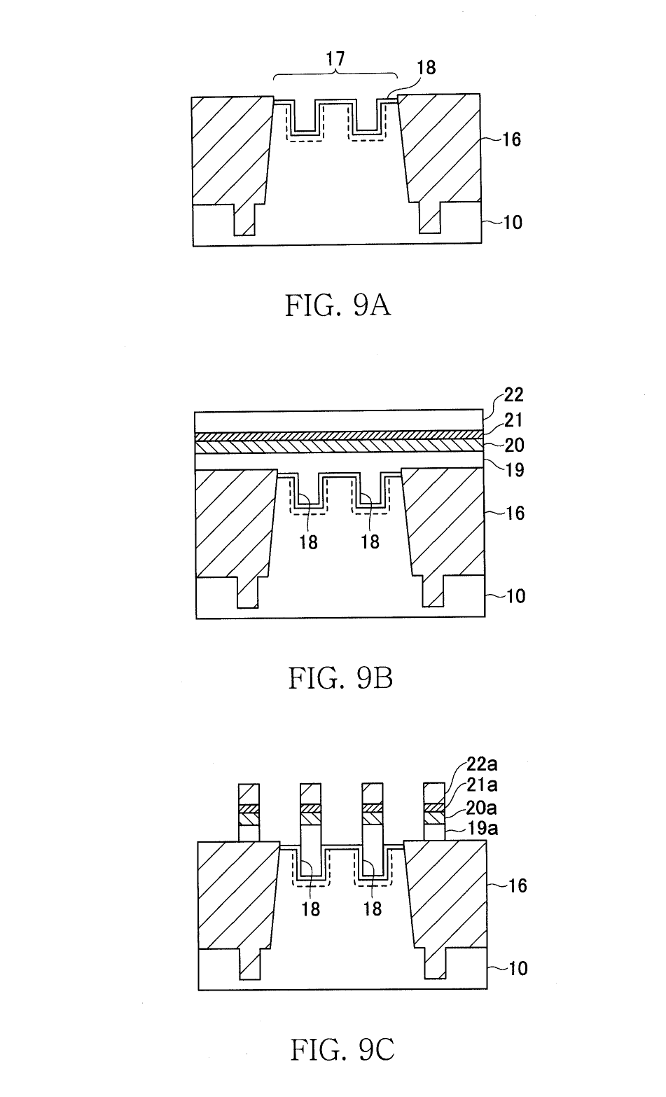

A gate oxide film 18 is formed on an inner wall of the gate trench 10a (FIG. 9A). In the formation of the gate oxide film 18, the whole surface of the substrate including the inner wall of the gate trenches 10a is thermally oxidized to form a thin silicon-oxide film (a sacrifice oxide film). By removing this sacrifice oxide film, damage on the surface of the active region 17 is repaired. Thereafter, the active region 17 is thermally oxidized at 800 to 1,100° C., thereby forming the gate oxide film (a silicon oxide film) 18 having a thickness of about 6 to 8 nm.

Next, a gate electrode is formed on the inside and the upper part of the gate trench 10a. In the formation of the gate electrode, a polysilicon film (a doped polysilicon film) 19 doped with an N-type impurity such as phosphorus (P), a tungsten nitride (WNx) film 20, a tungsten (W) film 21, and a silicon nitride film 22 are deposited sequentially (FIG. 9B). In the formation of the polysilicon film 19, the CVD method can be used. A thickness of the polysilicon film 19 should be set so that the gate trench is embedded completely. Meanwhile, the tungsten nitride film 20 and the tungsten film 21 can be formed by sputtering. Because the tungsten nitride film 20 is used as a barrier layer, a thickness of the tungsten nitride film 20 can be sufficiently small to about 5 to 10 nm. On the other hand, a thickness of the tungsten film 21 is preferably about 5 to 30 nm. The silicon nitride film 22 can have a thickness of about 20 nm, and this film can be deposited by CVD.

Next, the silicon nitride film 22 is patterned to form a gate cap insulation film 22a on the gate trench 10a (FIG. 9C). Thereafter, the doped polysilicon film 19, the tungsten nitride film 20, and the tungsten film 21 are dry etched, using the gate cap insulation film 22a as a mask, thereby completing a gate electrode of trench gates structure including a polysilicon film 19a, a tungsten nitride film 20a, and a tungsten film 21a (FIG. 9C).

Thereafter, an LDD region 23, a sidewall insulation film 24, a source/drain region 25, an interlayer insulation film 26, and a cell contact plug 27 are formed by a known method respectively, thereby completing a cell transistor 100 having trench gates structure (FIG. 10).

As explained above, according to the embodiment, after the gate trenches 10a are formed on the silicon substrate 10, the active regions 17 partitioned by the element isolation region 16a are formed. Therefore, an ideal trench shape can be obtained, without generating flashes of the silicon substrate material within the gate trenches 10a. Consequently, the cell transistor of trench gates structure having a satisfactory characteristic can be achieved.

The present invention has thus been shown and described with reference to specific embodiments. However, it should be noted that the present invention is in no way limited to the details of the described arrangements but changes and modifications may be made without departing from the scope of the appended claims.

In the above embodiment, a polymetal gate structure including a polysilicon film, a tungsten nitride film, and a tungsten film as gate electrode materials is explained. However, the present invention is not limited to the above structure, and various conductive materials and structures can be also employed.

What is claimed is:

1. A method for forming trench gates, comprising the steps of:
forming gate trenches on a semiconductor substrate; and
forming an element isolation region on the semiconductor substrate on which the gate trenches are formed.

2. The method for forming trench gates as claimed in claim 1, further comprising a step of channel doping within the gate trenches before the element isolation region is formed after the gate trenches are formed.

3. The method for forming trench gates as claimed in claim 1, further comprising the steps of:
forming a gate oxide film on the inner wall of the gate trenches; and
embedding a gate electrode material within the gate trenches.

4. The method for forming trench gates as claimed in claim 1, wherein the element isolation region is formed by STI method.

5. The method for forming trench gates as claimed in claim 1, wherein the step of forming the element isolation region includes a step of forming an element isolation trench so as to form a trench that reflect the gate trenches on a bottom of the element isolation trench.

6. The method for forming trench gates as claimed in claim 5, wherein the step of forming the element isolation region further includes the steps of embedding an element isolation film in the element isolation trench, and polishing the surface of the element isolation film.

7. A method for manufacturing a semiconductor device, comprising the steps of:
forming gate trenches on a semiconductor substrate;
channel doping within the gate trenches;
forming an element isolation region on the semiconductor substrate on which the gate trenches are formed;
forming a gate oxide film on the inner wall of the gate trenches; and
embedding a gate electrode material within the gate trenches.

8. The method for manufacturing a semiconductor device as claimed in claim 7, wherein the step of forming the element isolation region includes a step of forming an element isolation trench so as to form trenches that reflect the gate trenches on a bottom of the element isolation trench.

9. The method for manufacturing a semiconductor device as claimed in claim 8, wherein the step of forming the element isolation region further includes the steps of embedding an element isolation film in the element isolation trench, and polishing the surface of the element isolation film.
